(19) United States
(12) Patent Application Publication
(10) Pub. No.: US 2013/0126858 A1
(43) Pub. Date: May 23, 2013

(54) ORGANIC ELECTROLUMINESCENT DEVICE

(71) Applicants: Herbert Friedrich Boerner, Aachen (DE); Volker Van Elsbergen, Aachen (DE); Holger Schwab, Aachen (DE); Sören Hartmann, Baesweiler (DE); Detlef Raasch, Roetgen (DE)

(72) Inventors: Herbert Friedrich Boerner, Aachen (DE); Volker Van Elsbergen, Aachen (DE); Holger Schwab, Aachen (DE); Sören Hartmann, Baesweiler (DE); Detlef Raasch, Roetgen (DE)

(73) Assignee: Koninklijke Philips Electronics N.V., Eindhoven (NL)

(21) Appl. No.: 13/813,962

(22) PCT Filed: Aug. 1, 2011
(86) PCT No.: PCT/IB11/53415

§ 371 Date: Feb. 4, 2013

(30) Foreign Application Priority Data
Aug. 5, 2010 (EP) 10172057.1

(51) Int. Cl. H01L 51/52; H01L 33/52

(52) U.S. Cl. CPC H01L 51/52; H01L 33/52
USPC 257/40; 257/99

(57) ABSTRACT

The invention relates to an organic electroluminescent device (1), which is easily connectable to a socket in a cost-effective and reliable way. The organic electroluminescent device (1) comprising an electroluminescent layer stack (3, 4, 5) on top of a substrate (2) and a cover lid (6) encapsulating the electroluminescent layer stack (3, 4, 5), wherein the cover lid (6) comprises a least one electrical feedthrough (61) to electrically contact the electroluminescent layer stack (3, 4, 5) and at least one fastening element (62), where the at least one fastening element (62) is arranged to fasten the organic electroluminescent device (1) to a housing (8) such that forces to a backside of the cover lid (6b) during fastening of the housing (8) are minimized.

### FIELD OF THE INVENTION

The invention relates to the field of organic electroluminescent devices with cover lids comprising fastening elements and to light emitting units comprising such organic electroluminescent devices

### BACKGROUND OF THE INVENTION

Organic electroluminescent devices (or diodes) are devices, where organic molecules emit light when a driving voltage is applied to such organic electroluminescent devices (OLEDs). The OLEDs typically comprise a transparent substrate with a layer stack deposited on top of the substrate comprising an organic layer stack between two electrode layers, typically a tansparent anode layer on top of the substrate and a reflective cathode on top of the organic layer stack. Since the organic moleculs are sensitice to moisture and oxygen, the layer stack is encapsulated by a gas tight cover lid sealed on top of the substrate. Depending on the structure of the anode and/or the electrical feedthrought, the cover lids might be sealed partly on top of the anode or any other electrically conductive material. In order to operate the OLED, the OLED has to be placed into a socket providing an electrical connection to a power source supplying driving voltages in the order of a few volt, e.g. 2-10 V. The socket-base system of an OLED (as the base) and the socket being also the OLED holder shall be easily to be used, especially the OLED shall be connected to the socket easily.

Document U.S. 2010/0046210 discloses a socket-base system for OLEDs, where the OLEDs are fastened to a mount via mechanical/electrical couplers arranged at the backside of an OLED frame comprising the OLED as a plurality of protrusion to be inserted into complementary openings in the holder/housing with a one-directional movement. The interlock mechanism resembles that of the LEGO building blocks. In another embodiment, OLED devices are dircetly coupled to each other by pipe-like couplers fitting into each other or by protrusions fitting in corresponding metal inserts of adjacent OLEDs avoiding any housing for the OLEDs. These couplers are additional components to be added to the OLED devices. In contrast to that there is a demand to reduced the number of required components in order to provide a cost-effective socket-base system.

### SUMMARY OF THE INVENTION

It is an object of the invention to provide an organic electroluminescent device, which is easily connectable to a socket in a cost-effective and reliable way.

It is a further object of the present invention to provide a light emitting unit comprising such organic electroluminescent device.

This object is achieved by an organic electroluminescent device comprising an electroluminescent layer stack on top of a substrate and a cover lid encapsulating the electroluminescent layer stack, wherein the cover lid comprises at least one electrical feedthrough to electrically contact the electroluminescent layer stack and at least one fastening element, where the at least one fastening element is arranged to fasten the organic electroluminescent device to a housing such that forces to a backside of the cover lid during fastening of the housing are minimized. The cover lid commonly acts as an encapsulation for the electroluminescent layer stack of the organic electroluminescent device (OLED). In the present invention, additional functionalities are added to the cover lid, since the cover lid is simultaneously used to fasten the OLED to a housing. Commonly OLED devices comprise frames used to tightly fasten the OLED on one hand to the frame and to establish a connection between frame and housing. In this invention frames can be avoided reducing the required parts within a socket-base system, where the hosing acts as a socket providing electrical contacts and acts as a cavity at least partly accommodating the OLED, which reduces the manufacturing costs. Furthermore, the OLED itself (via the cover lid) is equipped with fastening elements making the connection to a housing fast and easy avoiding the use of OLED frames. The fastening element may exceed the substrate in a direction perpendicular to the light emission direction. Alternatively the fastening element may protude in a direction opposite to the light emission direction. The fastening element may in both cases be attached in such a way to the cover lid, such that during fastening of the housing to the cover lid direct forces to the backside of the cover lid may be avoided. The latter means that the forces applied during fastening of the housing to the cover lid are preferably transferred via the side walls of the cover lid to the substrate. Bending of the backside of the cover lid extending across the sensitive electroluminescent layer stack may thus be reduced or even avoided. The direct fastening of OLEDs into the housing improves the reliability of a socket-base system, because only a single connection is required in contrast to double connections of OLED-to-frame and frame-to-housing. A reduced number of required connection reduces the risk of connection problems and therefore will improve the reliability of the light emission from the OLED.

The organic electroluminescent device may utilize organic small molecules or polymers to produce light. Accordingly, OLEDs may be referred to as small molecule organic light emitting devices (SMOLEDs) or polymer light emitting devices (PLEDs). However, SMOLEDS are preferred because of their better light emission performance. The substrate is made of a transparent material, e.g. glass or plastic, having two essentially parallel surfaces. The side of the substrate facing towards the electroluminescent layer stack is also denoted as backside in the following. The side of the substrate opposite to the back side is denoted as light emitting side (or front side). The electroluminescent layer stack comprises at least two electrodes as anode and cathode and an organic light emitting layer in between. In other embodiments, there might be a plurality of organic layers arranged between the electrodes, such as hole transport layer, electron transport layer, hole blocking layers, electron blocking layers, one or more light emitting layers, e.g. comprising a host material with embedded light emitting molecules. A large number of different electroluminescent layer stacks comprising a different number/type of layers is known to skilled people, which are able to chose a suitable electroluminescent layer stack in dependence on the desired application. Typically, the electrode deposited on top of the substrate is a transparent anode, e.g. made of indium-tin-oxide (ITO). The other electrode, typically the cathode, is made of a reflective metal, e.g. Al. In some embodiment, there are additional layers present between the transparent anode and the substrate in order to improve the light outcoupling behaviour of the OLED. Additional hard layers may be deposited locally on top of the transparent anode in order to enable a contacting of the cathode from the side of the cover lid. Such hard layers have to be made of an electrically insulating material in order to avoid shorts between anode and cathode caused by the contacting of the cathode, e.g. with a contacting wires or a pin, form the backside (side of the cover lid).

In an embodiment the fastening element exceeds the substrate in a direction perpendicular to the light emission direction in order to avoid forces which may be applied to the electroluminescent layer stack during fastening the cover lid to the housing. The cover lid may exceed the subtrate in all directions, since the electroluminescent layer stack is contacted through the cover lid (backside of the cover lid) via at least one electrical feedthrough, also denoted as back-contacting. An electrical feedthrough comprises a conductive path from the inner side of the cover lid (facing towards the electroluminescent layer stack) to the outer side of the cover lid (or backside, the side opposite to the inner side). The electrical path is usually electrically insulated against the cover lid. Such insulation is required, if the cover lid is made of metal. In case of back-contacting, no contact areas on top of the backside of substrate outside the cover lid are required to contact the electroluminescent layer stack. Subsequently the cover lid can exceed the substrate partly or along all directions parallel to the backside of the substrate. The light emitting side is the side of the substrate, where at least the majority of light is emitted to the environment, and the side of the substrate opposite to the light emitting side is denotes as backside of the substrate. The light emission through to the light emitting surface of the substrate has a Lambertian characteristic, where the the maximum of light is emitted perpendiculat to the light emitting surface of the substrate, also called as light emission direction in the following. The term “exceeding” denotes the dimension of cover lid being longer than the corresponding dimension of the subtrate (or poking out of the substate) along a direction perpendicular to the light emission direction, which is perpendicular to the surface of the light emitting side of the substrate.

The cover lid is made of any material suitable to be equipped with electrical feedthroughs and rigid enough to be able to fasten the OLED to a housing. The fastening element may be the rim of the cover lid exceeding the substrate entirely or partly as the fastening element. Alternatively, the cover lid may comprise differently shaped fastening elements of a suitable shape to fasten the OLED to a housing. The material of at least the fastening means may be metal or plastic. The remaining material of the cover lid may be metal or plastic as well as a ceramic material or glass. The cover lid is sealed to the substrate in order to establish an encapsulation by a sealing material, e.g. a contiguous line of glass frit (non-conductive) or conductive epoxy glue, around the electroluminescent layer stack, to provide a gas tight seal against moisture and oxygen. The term “fasten the OLED” denotes the inserting the OLED into a housing, which provides a tight fit of the OLED to the housing, preferably independently from the location and/or orientation, where the housing is placed. Therefore at least the fastening element exceed the substrate of at least 1 mm, preferably more than 5 mm, to provide a tight fit to the housing.

In another embodiment the fastening element is a male or female part of a bayonet connector or is at least one element of the group of elements comprising a plate, a flap, a latch, or a hook. Here, the bayonet connector (or bayonet mount) is a fastening mechanism consisting for example of a male side with one or more pins, and a female receptor with matching L slots and spring(s) to keep the two parts locked together. To couple the two parts, the pin(s) on the male are aligned with the slot(s) on the female and the two pushed together. Once the pins reach the bottom of the slot, the two parts are turned in opposite directions to guide the pin across the bottom of the L shaped slot. The spring then holds the pin in position to prevent it from backing out. To disconnect, the two parts are pushed together to overcome the spring whilst twisting slightly to reverse the locking turn. The strength of the joint relies on the shear strength of the pins and the strength of the L slots which hold the pins in place when locked. A practised user can connect them quickly and they are not subject to cross-threading. In other embodiments the bayonet connector may be shaped differently within the scope of this invention. Alternatively a plate as a fastening element requires a slot or cavity to be inserted into at the housing, the same holds for flaps and latches. Hooks can be inserted into corresponding holes or bolts or behind pins to fix the OLED to a housing. All these fastening elements enable a fast locking of the OLED to a housing and on demand a fast removal of the OLED from the housing. The fast fastening and/or removal may be required at OLED walls equipped with OLED tiles, where the arrangedmant of the OLEDs shall be changed on demand.

In another embodiment the fastening element is attached at a backside of the cover lid or is attached to a sealing part of the cover lid. In cases, where the gap between substrates of adjacent OLED present in a housing for multiple OLED shall be as small as possible, preferably without any gap between adjacent OLEDs, the fastening elements are arranged at the backside of the cover lid enabling a wider freedom of mechanical design for the housing to provide a tight fit together with the closely arranged substrate of adjacent OLEDs. The backside of the cover lid denotes the side of the cover lid facing away from the substrate. On the other hand, fastening elements present at the sealing part of the cover lid enables to fasten the OLED to a housing with a small buidling depth, e.g. with flat cover lids having a backside arranged in a closer distance to the substrate. The sealing part denotes the area of the cover lid, where the lid is sealed to the substrate.

In another emodiment at least the fastening element of the cover lid is made of a magnetic material. A magnetic material can be fastened to a corresponding magnet present in a housing without the need of any additionally required mechanical locking means. Fixing OLEDs to housing with the use of magnets is realized in prior art by placing OLED in frames, which comprise magnets as additional components. Than the magnets of the frames are attached to metal parts present in the housings. In this invention, the cover lid made of magnetic material can be used instead of additional magnets to fasten the OLED to a housing. As an example, steel might be used as a magnetic material for the cover lid. The fastening can be achieved by placing one or more magnets of a suitable strength in the housing. The OLED can easily be reversibly attached to the housing. The advantage is, that no modification of the OLED cover lid is required to enabled a tight fit of the OLED in the housing.

In another embodiment at least one of the fastening elements, at least parts of the remaining cover lid and a sealing material are made of an electrical conductive material, preferably the cover lid is essentially made of electrical conductive material. Here, the cover lid might be used as an electrical path connected to one of the electrodes of the electroluminescent layer stack via the electrically conductive sealing material (e.g. epoxy glue with a conductive filler) when at least partly sealed on top of this electrode. A cover lid essentially made of electrical conductive material might be used not only to contact the electrode, but also to distribute the current applied to this electrode and therefore acting as a shunting structure. This shunting structure provides an improved homogeniety of the brightness of the OLED. The term “essentially” shall denote the entire cover lid excluding the areas of the cover lid, where electrical feedthroughs are present.

In another embodiment the volume between the cover lid and the substrate is filled with an inert fluid or gel providing a good heat conductivity between the electroluminscent layer stack and the cover lid, preferably the fluid or gel is a fluorinated fluid or silicone gel, more preferably a Sylgard 3-6636 silicone dielectric gel or a Dow Corning fluorogel Q3-6679 dielectric gel. OLEDs are currently operated at rather low power densities of about 30 W/m², with luminance values of typically 1.000 cd/m². In the future, much higher values of up to 10.000 cd/m² are envisaged. These higher luminance levels will lead to a substantial self-heating of the OLED, which requires a better cooling of the OLED. Metalic lids can provide a sufficient heat transfer to a housing for cooling purposes, if the heat conductivity between electroluminescent layer stack and metalic lids is sufficient. Currently, the volume inside the cover lid is filled with gas providing a too low heat conductivity. A fluid or gel filling the volume will improve the heat transfer from the electroluminescent layer stack to the cover lid. The fluid or gel has to be chemically inert against the organic layers within the electroluminescent layer stack. Therefore a fluorinated fluid of gel is preferred.

In another emodiment the at least one feedthrough is arranged as a pin extending to the outside of the cover lid or as a contact area suitable to be contacted with an electrical contact from the outside. Such contact from the outside might be a contact pin. Such shapes of the feedthrough at the backside of the cover lid are easy to be connected with a corresponding electrical path provided from a housing. The contact area denotes an area of a size significantly larger than a cross section of a pin. A pin exceeds the outer surface of the cover lid, while a contact area may by a protrusion in the outer side of the cover lid or may be one the same level as the outer side of the cover lid. Preferably, the contact area has a flat and smooth surface. The pin might have a rounded or sharp tip at its top.

The invention further relates to a light emitting unit comprising at least one organic electroluminescent device according to the present invention and at least one housing, wherein the housing is adapted to provide electrical contacts to the organic electroluminescent device and comprises one or more receiving elements adapted to the fastening means to fasten the organic electroluminescent device via the fastening means to the housing. A housing could be any cavity of any shape suitable to at least partly accommodate the OLED. To be able to fasten the OLED, the housing has to comprise receiving elements adapted to provide a tight fit to the correspondingly shaped fastening element of the OLED. The receiving element might be made of any suitable material such as metal, plastic or any other material. Preferably the one or more receiving elements and the at least one fastening element establish a bayonet connector or the one or more receiving elements are arranged to fasten the at least one fastening elements of the organic electroluminescent device arranged as at least one element of the group of elements comprising a plate, a flap, a latch, or a hook. The electrical contacts in the housing are further connected to a power source in order to apply a driving voltage to the OLED via the electrical contacts within the housing. The power souce may be integrated in the housing or may be located externally. The power source may be any power source suitable to provide a driving voltage in the order of a few volts, e.g. 2-15V. The connection to the power source may be established by wires connected (e.g. welded or soldered) to the electrical contacts or may be established by other conductive paths (e.g. conductive layers) connected to the electrical contacts. The electrical contacts itself may be conductive layers, wires, pins or other suitable means to establish an electrical contact to the OLED, where the term “electrical contact” always denotes the separate contacting of anode and cathode of the electroluminescent layer stack of the OLED via the cover lid of the OLED, either directly to the cover lid and/or via electrical feedthroughs arranged within the cover lid.

In another embodiment the housing comprises at least one magnet, preferably at least parts of the one or more receiving elements are arranged as magnets, in order to fasten the cover lid of the organic electroluminescent device, where at least the fastening element of the cover lid is made of a magnetic material. The magnets have to arranged at suitable locations of the housing adapted to the shape of the cover lid and/or the fastening elements. Suitable magnets are common permanent magnets. Preferably at least one of the magnets provide an electrical contact to the cover lid when the magnetic material is also electrically conductive. In case of magnets made of electrically non-conductive magnetic material, these magnets might be coated with an electrical coating to provide a magnet suitable to be used as electrical contact. This will avoid additional electrical contacts within the housing to connect the OLED to a power source. The magnets of the housing can easily be contacted from its backside with a wire or other electrical connection means. The mechanical fixation, which is simultaneously also at least one of the electical contacts further simplifies the construction of the OLED and the socket-base system of OLED and housing. A magnet as electrical contact provides a reliable contact even in case of slight mechanical movements of housing and/or OLED.

In another embodiment the one or more receiving elements are made of an electrical conductive material in order to provide an electrical contact to the organic electro-luminescent device via the at least one fastening element. The receiving elements are connected to the cover lid to fasten the OLED. If the receiving elements are simultaneously used as electrical contacts, the functions of mechanical fixation and electrical connection can be integrated in one component, which saves component costs. In case of two electrically separated receiving elements connected to a power source and a suitable cover lid comprising separated electrically conductive paths connecting anode and cathode of the electroluminescent layer stack separately (e.g. via the sealed locally conductive cover lid and the conductive sealing material to the anode and via an electrical feedthrough in the cover lid to the cathode, alternatively via two separate feedthroughts in the cover lid) the OLED can easily be electrically connnected to a power source via the receiving elements and the cover lid.

In an alternative embodiment the housing comprises at least one pin made of electrical conductive material, preferably the pin being spring loaded, to electrically contact the cover lid and/or at least one electrical insulated feedthrough within the cover lid to provide an electrical contact to anode and/or cathode of the organic electroluminescent layer. Here one electrical contact (or electrical connection) to at least one feedthrough is not established via the receiving elements but to the backside of the cover lid, where electrical feedthroughs are located. This offers the possibility to manufacture the receiving elements as a single component, e.g. made of metal and e.g. providing an electrical contact to the cover lid via the fastening element. The second electrical contact is established by direct contacting the electrical feedthrough within the cover lid. In case of a feedthrough providing a contact area, a pin can easily provide an electrical connection between contact area of the feedthrough and a power source be touching the contact area. In this case the cover lid could be made of metal being electrical conductive entirely (with feedthrough(s) electrically insulated against the cover lid) or has to comprise suitable conductive parts. Such conductive parts may be established by a cover lid partly made of metal or by depositing a suitable conductive layer on top of the cover lid to provide an electrical contact to one of the electrodes, e.g. to the anode. Alternatively, both anode and cathode may by connected via two separate feedthroughs contacted by two separate pins within the housing. In the latter case the cover lid not necessarily have to be made of metal. Also non-conductive material can be used as cover lid material. In case of a spring loaded pin, the spring will apply a sufficient force to the pin to establish a reliable continuous electrical contact of the pin to the contact area. The spring force has to be adapted to a suitable force not to bend the cover lid touching the electroluminescent layer stack. People skilled in tha art are able to chose a sufficient spring force depending on thicknesses amd sizes of the cover lid and the distance between cover lid and the electroluminescent layer stack.

In another embodiment the housing comprises a heat sink structure in contact to at least parts of the cover lid of the organic electroluminescent device. OLED are currently operated at rather low power densities of about 30 W/m², with luminance values of typically 1.000 cd/m². In the future, much higher values of up to 10.000 cd/m² are envisaged. These higher luminance levels will lead to a substantial self-heating of the OLED, which requires a better cooling of the OLED. Metalic lids can provide a significant heat transfer to a housing (significant cooling of the OLED), if the heat conductivity between the OLED and the housing is suifficient. A heat sink in contact to a metal cover lid provides such good heat conductivity. The heat sink structure could by any suitable structure, e.g. a heat sink structure as applied to semi-conductor circuits. In a preferred embodiment the heat sink structure is a heat paste filling at least partly the gap between cover lid and housing to avoid an air gap between OLED and housing. Such air gaps would reduce a heat transfer drastically, up to a factor of 8000. A direct contact between OLED and housing, e.g. made of metal in the area in contact with the heat paste and optionally connected to another heat sink arranged on the backside of the housing, provides a good heat transfer away from the OLED. Ceramic based, metal based and carbon-based heat pastes are on the market today. The thermal conductivity of such heat pastes could be up to 200 W/mK or more, e.g. 218 for berylliumoxide-paste or 170 for aluminumnitride-paste, which is about half of the thermal conductivity of copper (380 W/mK) or silver (429 W/mK). The pastes commonly comprise metal oxide and/or nitride particles suspended in silicone thermal compounds. Preferably the heat paste is arranged ouside the area of electrical feedthroughts and/or electrical contacts (e.g. metal pins), because heat pastes might be electrically conductive and would cause shots between anode and cathode contacts if covering cover lid and feeedthroughs as a single layer.

### BRIEF DESCRIPTION OF THE DRAWINGS

These and other aspects of the invention will be apparent from and elucidated with reference to the embodiments described hereinafter.

In the drawings:

FIG. 1 shows two embodiments of an organic electroluminescent device and a housing according to the present invention with (a) the fastening elements arranged at the sealing part of the cover lid, and (b) the fastening elements arranged at the backside of the cover lid.

FIG. 2 shows another embodiment of the housing comprising magnets.

FIG. 3 shows an embodiment of a light emitting unit according to the present invention with the receiving element of the housing as one of the electrical contacts.

FIG. 4 shows another embodiment of a light emitting unit according to the present invention with two electrical contacts in the housing arranged as spring loaded pins.

FIG. 5 shows another embodiment of a light emitting unit according to the present invention with the receiving element of the housing as one of the electrical contacts and a spring loaded pin as the other electrical contact arranged in the housing.

FIG. 6 shows another embodiment of a light emitting unit according to the present invention with two electrical contacts in the housing arranged as spring loaded pins, where the cover lid is made of non-conductive material.

FIG. 7 shows another embodiment of a light emitting unit according to the present invention comprising a heat paste as a heat sink structure between housing and organic electrolumninescent device.

FIG. 8 shows another embodiments of an organic electroluminescent device and a housing according to the present invention with the fastening elements arranged at the backside of the cover lid protuding in a direction opposite to the light emission direction.

### DETAILED DESCRIPTION OF EMBODIMENTS

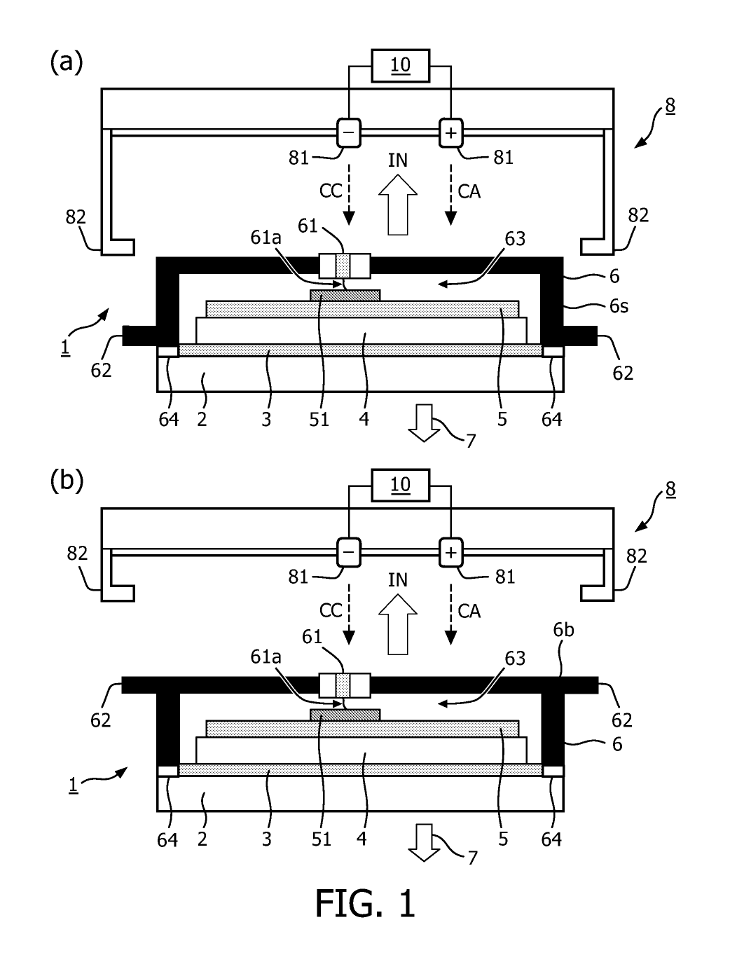

FIG. 1 shows two embodiments of an organic electroluminescent device 1 and a housing 8 according to the present invention with (a) the fastening elements 62 arranged at the sealing part 6s of the cover lid 6, and (b) the fastening elements 62 arranged at the backside 6b of the cover lid 6. Here, the organic electroluminescent device 1 comprises an electroluminescent layer stack 3, 4, 5 on top of a substrate 2 and a cover lid 6 encapsulating the electroluminescent layer stack 3, 4, 5. The substrate is made of a transparent material, such as glass or plastic (e.g. PMMA or PET). The electroluminescent layer stack comprises at least a first transparent electrode 3 on top of the substrate 2, typically the anode 3 made of indium-tin-oxide (ITO), an organic light emitting layer 4 or layer stack 4 on top of the first electrode 3 and a second electrode 5 on top of the organic light emitting layer 4 or layer stack 4, typically the cathode 5 made of a reflective material such as aluminum. The light emitting layer 4 may comprise an organic host material and embedded light emitting molecules. In several cases the layer 4 comprises additional layers forming a layer stack 4. These additional layers may comprise one more more layers of the group of hole transport layer, electron transport layer, hole blocking layer, electron blocking layer, additional organic light emitting layer(s). Several electroluminescent layer stacks are known. People skilled in the art are able to chose the appropriate electroluminescent layer stack for the particular application. The cover lid 6 could be made of any material suitable to encapsulate the electroluminescent layer stack 3, 4, 5 against moisture and oxygen from the environment. However, this material should be at least suitable to accommodate electrical feedthroughts 61 in a gas tight way in order to contact the anode 3 and the cathode 5. The cover lid 6 is connected to the substrate 2 and/or to the anode 4 on top of the sustrate by a conductive sealing material 64. The sealing material 64 (e.g. epoxy glue) could be doped with metal particals to become electrically conductive. The cover lid 6 further comprises at least one electrical feedthrough 61 to electrically contact at least one of the electrodes 3, 5 and at least one fastening element 62 exceeding the substrate 2 in a direction perpendicular to the light emission direction 7. In FIG. 1 there are two fastening elements 62 arranged to fasten the organic electroluminescent device 1 to a housing 8, which comprises two corresponding receiving elements 82 to accommodate the fastening elements 62. The material of the receiving elements 82 is any material suitable to fasten the OLED 1, e.g. metal or plastic or other like wood etc. The fastening structure is shown only schematically in FIG. 1. The two receiving elements 82 and the two fastening elements 62 may establish a bayonet connector or may be arranged to fasten the two fastening elements 62 of the organic electroluminescent device 1 arranged as plates, flaps, latches, or hooks. The fastening elements 62 may be fixed into the cooresponding part of the bayonet connector via springs pushing onto the fastening elements 62. People skilled in the art are able to chose the appropriate shape of a bayonet connector. A fastening element 62 as latch, plate or flap would be inserted into a corresondingly shaped cavity as the receiving element 82. The insertation could be performed via a translational motion or via a rotational mortion, depending on the shape of the housing 8, the OLED 1 and/or the cover lid 6, 62. The material of the fastening elements 62 could be any material suitable to fasten the OLED 1 to the housing 8. Preferably the fastening elements 62 are made of the same material as the remaining cover lid 6. More preferably the cover lid 6 comprising the fastening elements 62 is a single piece component 6. After inserting IN the organic electroluminescent device 1 into the housing 8, a light emitting unit is formed. When a driving voltage is applied to the organic electroluminescent device 1 by a suitable power source 10 (e.g. comprising further drivers etc.), the OLED 1 will emit light 7 through the substrate 2. The main direction of the light emission 7 is perpendicular to the front side of the substrate 2 facing away from the electroluminescent layer stack 3, 4, 5. The fastening elements 62 are arranged perpendicular (vertical) to the direction of light emission 7 exceeding the substrate 2 in order to fit into corresponding receiving elements 82 of the housing 8. Depending on the shape of the housing 8, the fastening elements 62 may be arranged at the sealed part 6s of the cover lid 6 close to the sealing material 64 or may be arranged at the backside 6b of the cover lid 6. In the first case, the receving elements 82 may be arranged to end at the same level as the front side of the substrate 2 in order to provide a smooth surface of the light emitting unit. In the latter case, the OLED 1 will poke out of the housing 8, which could be desired in other cases. The electrical contacts in FIG. 1 are established by two electrical contacts 81 located in the housing 8 opponent to the backside 6b of the cover lid 6 when inserted IN into the housing 8. The contact for the anode is arranged to contact the cover lid 6 somewhere outside the feedthrough 61. Here the cover lid is made of metal. Together with an electrically conductive sealing material 64 and an anode 3 being in electrical contact to the sealing material 64, the positive voltage provided by the power source 10 is applied to the anode 3 via a wire connected to the electrical contact 81 within the housing 8 being in electrical contact (indicated by the dashed arrow CA) with the metal cover lid 6 further in electrical contact with the anode 3 via the electrical conductive sealing material 64 being in electrical contact to the anode 3. The negative voltage is provided by the power source 10 via a wire connected to the electrical contact 81 within the housing 8 being in electrical contact to the feedthrough 61 (insulated against the metal cover lid as indicated by the white area around the gray area 61) as indicated by the dashed arrow CC, further being in electrical contact with the cathode 5 via the electrical bridge 61 a between feedthrough and cathode. Such bridge could be established e.g by conductive glue 51 or by a wire arranged between the conductive glue 51 and the feeedthrough 61. In order not to damage the electroluminescent layer stack 3, 4, 5, especially not to cause a short between anode 3 and cathode 5, there might be a hard non-conductive layer arranged locally underneath the conductive glue 51 between anode 3 and organic light emitting layer 4. The feedthrough 61 might comprise a contact pin or might be arranged as a flat conductive surface to be connected to the electrical conatcs 81 of the housing 8.

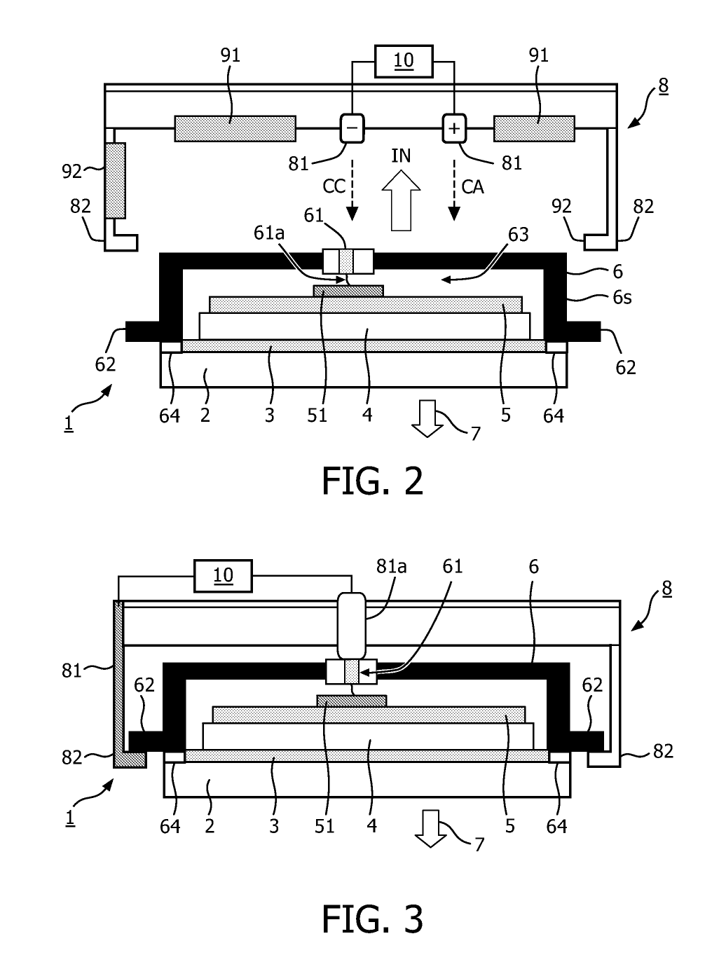

FIG. 2 shows another embodiment of the housing 8 comprising magnets 91, 92. The magnets 91 may be arranged at any suitable position to fasten and/or to support the fastening (in addition to the fastening provided be the receiving elements 82) of the OLED 1 in the housing 8. The shown housing with two magnets 91 is only one example. In other embodiments within the scope of the present invention the number, size and location of the magnets might vary. In an alternative embodiment the magnets 92 are arranged as parts of the receiving elements 82. Both alternatives are able to fasten the cover lid 6 of the organic electroluminescent device 1 when the fastening elements 62 and/or the cover lid 6 are made of a magnetic material, e.g steel or any other suitable metal.

FIG. 3 shows an embodiment of a light emitting unit according to the present invention with the receiving element 62 of the housing 8 arranged as one of the electrical contacts 81 as indicated with the gray area of the left receiving element 82. In contrast to FIG. 1, this embodiment requires only one electrical contact 81 at the backside of the cover lid 6. The double functionality of the receiving element 82 providing a tight fit of the OLED 1 and providing an electrical contact 81, e.g. to the anode 4, allows to reduce the number of components for the housing 8. The contact 81 at the backside of the cover lid is established by a pin 81a in contact to the feedthrough 61.

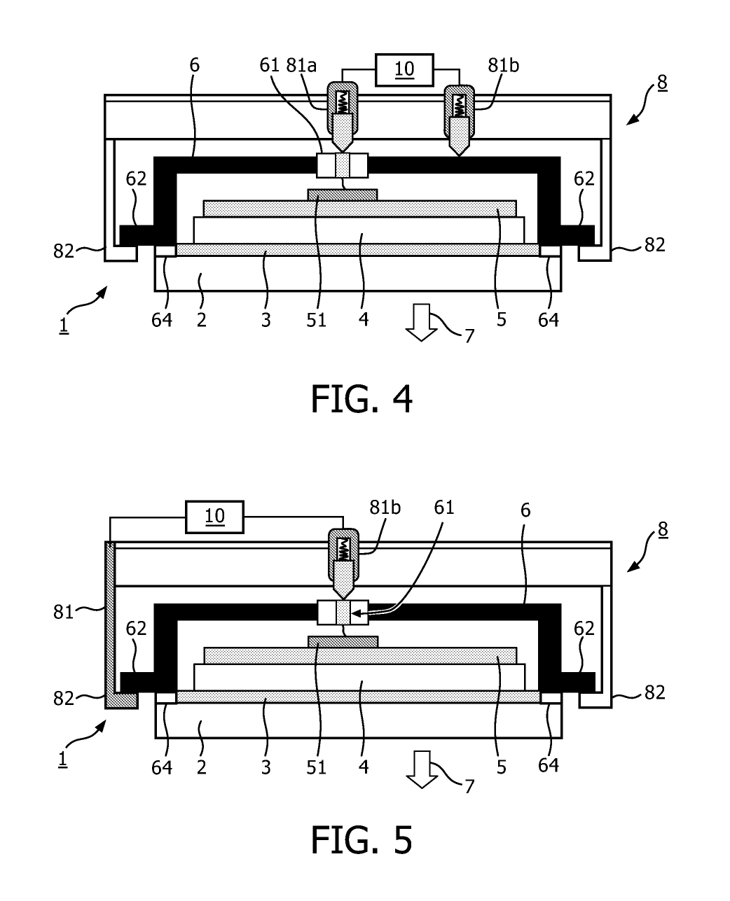

FIG. 4 shows another embodiment of a light emitting unit according to the present invention with two electrical contacts 81 in the housing 8 arranged as two spring loaded pins 81b. The electrical connection between power source 10 and OLED (anode 3, cathode 5) corresponds to the description of the electrical connection in FIG. 1. The spring loaded pins 81b enable to apply a certain maximum pressure to the cover lid 6 in order to avoid a bending of the cover lid eventually resulting in a cover lid touching the electroluminescent layer stack 3, 4, 5, which could damage the electroluminescent layer stack 3, 4, 5. Furthermore, the spring loaded pins 81b will provide a reliable electrical connection to feedthroughs 61 and/or cover lid 6 even in case of small mechanical movements of the OLED 1 in the housing 8, since the springs provide an elastic connection.

FIG. 5 shows another embodiment of a light emitting unit according to the present invention with the receiving element 82 of the housing 8 as one of the electrical contacts 81 and a spring loaded pins 81b as the other electrical contact 81 arranged in the housing 8. FIG. 5 is an advatageous combination of the emodiments shown in FIGS. 3 and 4.

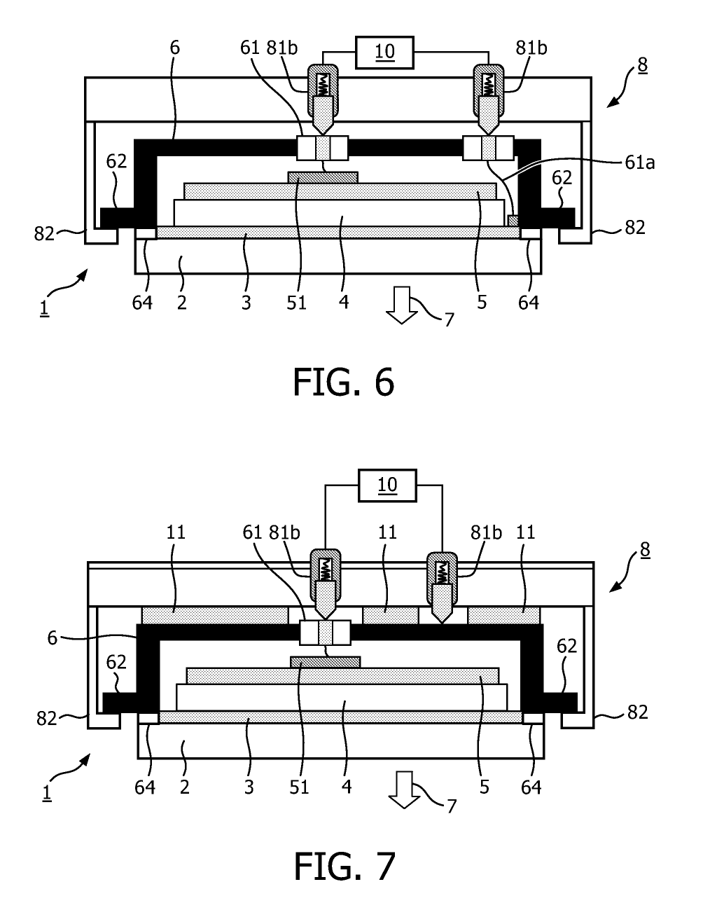

FIG. 6 shows another embodiment of a light emitting unit according to the present invention with two electrical contacts 81 in the housing 8 arranged as two spring loaded pins 81b. The electrical connection between power source 10 and OLED (anode 3, cathode 5) corresponds to the description of the electrical connection in FIG. 1. The spring loaded pins 81b enable to apply a certain maximum pressure to the cover lid 6 in order to avoid a bending of the cover lid eventually resulting in a cover lid touching the electroluminescent layer stack 3, 4, 5, which could damage the electroluminescent layer stack 3, 4, 5. Furthermore, the two spring loaded pins 81b will provide a reliable electrical connection to the two feedthroughs 61 even in case of small mechanical movements of the OLED 1 in the housing 8, since the springs provide an elastic connection. In this embodiment, the cover lid does not have to be conductive, since the anode 3 is contacted to the spring loaded pin similar like the cathode 5, with an electrical bridge 61 a between feedthrough and anode 3. Such bridge could be established e.g by conductive glue 51 or by a wire arranged between the conductive glue 51 and the feeedthrough 61. Alternatively to a non-conductive cover lid 6, the cover lid 6 might also be conductive. Furthermore the sealing material 64 might be non-conductive, e.g. glass-frit. Here, all combinations of conductive/non-conductive cover lids 6 and/or conductive/non-conductive sealing materials 64 might be used, because the electrical contacting of cathode 5 and anode 3 are provided through feedthroughs 61a electrically insulated against the cover lid 6.

FIG. 7 shows another embodiment of a light emitting unit according to the present invention comprising a heat paste 11 as a heat sink structure between housing 8 and organic electrolumninescent device 1. Ceramic based, metal based and carbon-based heat pastes are available on the market today. The thermal conductivity of such heat paste could be up to 200 W/mK or more, e.g. 218 for berylliumoxide-paste or 170 for aluminumnitride-paste, which is about half of the thermal conductivity of copper (380 W/mK) or silver (429 W/mK). The pastes commonly comprise metal oxide and/or nitride particles suspended in silicone thermal compounds. In case of electrically conductive heat pastes 11, the heat paste has to be arranged ouside the area of electrical feedthroughts 61 and/or electrical contact 81, 81a, 81b, as shown in FIG. 7. The housing may further comprise a conventional heat sink (not shown here) at the backside of the housing (side of the housing facing away from the OLED 1), which is in direct contact to the heat paste or the hosuning in between the heat paste and the heat sink is made of metal (however insulated against the electrical contact 81). To improve the heat transfer, also the electroluminescent layer stack 3, 4, 5 should be thermally coupled to the cover lid 6. Usually, the encapsulated volume 63 is filled with gas having a poor thermal conductivity. The heat transfer from the electroluminescent layer stack 3, 4, 5 to the cover lid 6 can be significantly improved by filling the volume 63 with an inert fluid or gel providing a good heat conductivity between the electroluminscent layer stack 3, 4, 5 and the cover lid 6, preferably the fluid or gel is a fluorinated fluid or gel, e.g. a silicon gel. Suitable gels are for example Sylgard 3-6636 silicone dielectric gel or Dow Corning fluorogel Q3-6679 dielectric gel.

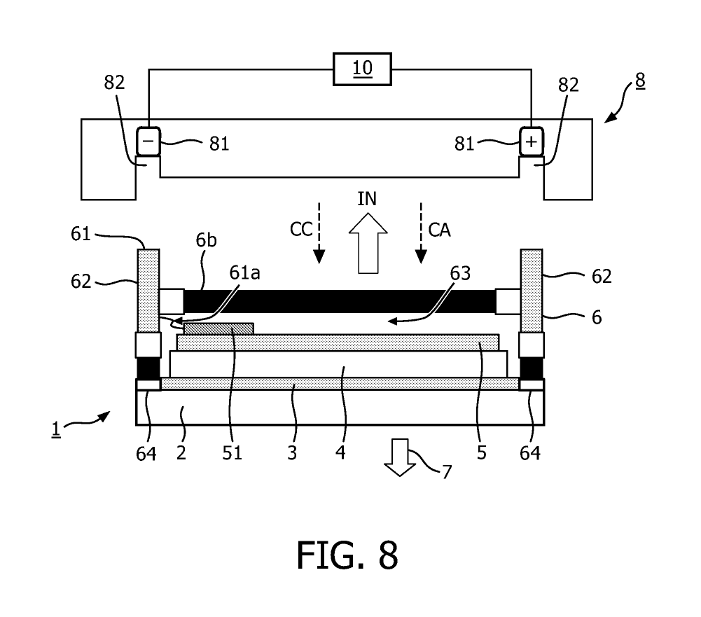

In an alternative embodiment of the present invention shown in FIG. 8, the fastening elements 62 protrude in a direction opposite to the light emission direction 7. The fastening elements 62 are arranged directly above the sealing part of the cover lid 6s in order to avoid or at least limit forces which may be applied to the electroluminescent layer stack by means of the backside of the cover lid 6b during fastening of the cover lid 6 to the housing 8. This allows an easy fastening of the cover lid 6 by inserting the protruding fastening elements 62 into corresponding receiving elements 82 in the housing 8. The fastening element 62 may extend around the whole circumference of the cover lid 6 such that the cross section of the cover lid may look like a H as shown in FIG. 8 in order to provide a stable and reliable fastening of the housing 8. Alternatively, two or more fastening elements 62 may be provided at the edge of the cover lid 6 protruding in a direction opposite to the light emission direction 7. The protruding fastening elements 62 may also be used as feedthrough 6l as shown in FIG. 8 in order to provide electrical contacts to the anode and the cathode.

In other embodiments not explicitly shown here, the number of electrical contacts 81 may be more than 2. In an embodiment, the cover lid 6 comprises multiple feedthroughs 61 in order to contact the cathode 5 in parallel to improve the current distribution within the cathode 5. In another emodiment, all receiving elements 62 are arranged as electrical contacts 81 to the cover lid 6 in order to improve the current distribution for the anode 3. In another embodiment, the cover lid 6 may comprise multiple feedthroughs 61 in order to contact multiple anodes 3 and multiple cathode 5 of a structured OLED 1 comprising multiple electrically separated electroluminescent layer stacks 3, 4, 5. In another embodiment the cover lid 6 may comprise multiple feedthroughs 61 in order to contact multiple intermediate electrodes (not shown here) present in between of vertically stacked electroluminescent layer stacks of so-called stacked OLEDs.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

### LIST OF REFERENCE SIGNS

1 organic electroluminescent device
2 substrate
3 first electrode, typically the anode
4 organic light emitting layer (stack)
5 second electrode, typically the cathode
51 conductive glue
6 cover lid
61 feedthrough within the cover lid
61a conductive bridge to the electrical feedthrough
62 fastening elements
63 volume encapsulated from the cover lid
64 sealing material, e.g. glass frit or epoxy glue with conductive filler
6s sealing part of the cover lid
6b backside of the cover lid
7 light emission direction
8 housing
81 electrical contact
81a electrical contact as pin
81b electrical contact as spring loaded pin
82 receiving element
91 magnet within the housing
92 magnet arranged within the receiving element of the housing
10 power source
11 heat sink structure, especially a heat paste
CC electrical contact to the cathode
CA electrical contact to the anode
IN inserting the OLED into the housing

1. An organic electroluminescent device comprising an electroluminescent layer stack on top of a substrate and a cover lid encapsulating the electroluminescent layer stack, wherein the cover lid comprises at least one electrical feedthrough to electrically contact the electroluminescent layer stack and at least one fastening element, the at least one fastening element being arranged to fasten the organic electroluminescent device to a housing such that forces applied to the cover lid during fastening of the housing are minimized by transferring the forces via the side walls of the coverlid to the substrate such that bending of a backside of the cover lid is reduced.

2. The organic electroluminescent device according to claim 1, wherein the fastening element constitutes a part of a bayonet connector.

3. The organic electroluminescent device according to claim 1, wherein the fastening element is attached at a backside of the cover lid or is attached to a sealing part of the cover lid.

4. The organic electroluminescent device according to claim 1, wherein the fastening means extends beyond the substrate in a direction perpendicular to the light emission direction.

5. The organic electroluminescent device according to claim 1, at least the fastening element of the cover lid comprises a magnetic material.

6. The organic electroluminescent device according to claim 1, wherein at least one of the fastening elements at least parts of the remaining cover lid and a sealing material comprise an electrical conductive material.

7. The organic electroluminescent device according to claim 5, wherein the volume (between the cover lid and the substrate is filled with an inert fluid or gel providing a good heat conductivity between the electroluminescent layer stack and the cover lid.

8. The organic electroluminescent device according to claim 1, wherein the at least one feedthrough is arranged as a pin extending to the outside of the cover lid or as a contact area suitable to be contacted with an electrical contact from the outside.

9. A light emitting unit comprising at least one organic electroluminescent device according to claim 1 and at least one housing, wherein the housing is adapted to provide electrical contacts to the organic electroluminescent device and comprises one or more receiving elements adapted to the fastening means to fasten the organic electroluminescent device via the fastening means to the housing.

10. The light emitting unit according to claim 9, wherein the one or more receiving elements and the at least one fastening element establish a bayonet connector or the one or more receiving elements are arranged to fasten the at least one fastening elements of the organic electroluminescent device arranged as at least one element of the group of elements consisting of a plate, a flap, a latch, and a hook.

11. The light emitting unit according to claim 9, wherein the housing comprises at least one magnet, in order to fasten the cover lid of the organic electroluminescent device, where at least the fastening element of the cover lid comprises a magnetic material.

12. The light emitting unit according to claim 11, wherein at least one of the magnets provide an electrical contact to the cover lid.

13. The light emitting unit according to claim 9, wherein at least one of the one or more receiving elements are made of an electrical conductive material in order to provide an electrical contact to the organic electroluminescent device via the at least one fastening element.

14. The light emitting unit according to claim 9, wherein the housing comprises at least one pin made of electrical conductive material, the pin being spring loaded, to electrically contact the cover lid and/or at least one electrical insulated feedthrough within the cover lid to provide an electrical contact to a anode and/or cathode of the organic electroluminescent layer.

15. The light emitting unit according to claim 9, wherein the housing comprises a heat sink structure in contact to at least parts of the cover lid of the organic electroluminescent device.

16. The organic electroluminescent device according to claim 1, wherein the fastening element is selected from a group consisting of: a plate, a flap, a latch, and a hook.

17. The organic light emitting unit according to claim 15, wherein the heat sink structure comprises a heat paste filling at least partly the gap between cover lid and housing and outside the area of electrical feedthroughts and/or electrical contacts.
